(19) United States
(12) Patent Application Publication
(10) Pub. No.: US 2025/0357173 A1
(43) Pub. Date: Nov. 20, 2025

(54) ELECTROSTATIC CHUCK

(71) Applicant: Tokyo Electron Limited, Tokyo (JP)

(72) Inventor: Taketoshi TOMIOKA, Miyagi (JP)

(73) Assignee: Tokyo Electron Limited, Tokyo (JP)

(21) Appl. No.: 19/284,972

(22) Filed: Jul. 30, 2025

Related U.S. Application Data
(63) Continuation of application No. PCT/JP2024/009295, filed on Mar. 11, 2024.

(30) Foreign Application Priority Data
Mar. 16, 2023 (JP) 2023-042066

(51) Int. Cl. H01L 21/683; H01J 37/32

(52) U.S. Cl. CPC H01L 21/6833; H01J 37/32715; H01J 2237/2007

(57) ABSTRACT

A technique improves temperature uniformity in a substrate held by an electrostatic chuck. An electrostatic chuck includes a dielectric member on which a substrate is placeable, and an electrostatic electrode in the dielectric member. The dielectric member includes a first upper surface having a gas outlet through which a gas flows out, and an annular seal band. The seal band is outside the first upper surface and at a higher position than the first upper surface. The seal band includes an outer peripheral portion, and an inner peripheral portion having a smaller height than the outer peripheral portion. The electrostatic electrode is at least under the inner peripheral portion of the seal band.

### CROSS-REFERENCE TO RELATED APPLICATIONS

This application is a Continuation of PCT International Application No. PCT/JP2024/009295, filed on Mar. 11, 2024, which claims priority under 35 U.S.C. § 119(a) to Parent Application No. JP2023-042066, filed on Mar. 16, 2023 in Japan, all of which are hereby expressly incorporated by reference into the present application.

### FIELD

Exemplary embodiments of the disclosure relate to an electrostatic chuck (ESC).

### BACKGROUND

A technique described in Patent Literature 1 provides an electrostatic chuck (ESC) including an annular seal band for supporting an outer peripheral portion of a substrate.

### CITATION LIST

### Patent Literature

Patent Literature 1: Japanese Unexamined Patent Application Publication No. 2021-15820

### BRIEF SUMMARY

### Technical Problem

One or more aspects of the disclosure are directed to a technique for improving temperature uniformity in a substrate held by an ESC.

### Solution to Problem

An electrostatic chuck according to one or more embodiments includes a dielectric member on which a substrate is placeable, and an electrostatic electrode in the dielectric member. The dielectric member includes a first upper surface having a gas outlet through which a gas flows out, and a seal band being annular. The seal band is outside the first upper surface and at a higher position than the first upper surface. The seal band includes an outer peripheral portion, and an inner peripheral portion having a smaller height than the outer peripheral portion. The electrostatic electrode is at least under the inner peripheral portion of the seal band.

### Advantageous Effects

The technique according to one or more embodiments of the disclosure improves temperature uniformity in a substrate held by the electrostatic chuck.

### BRIEF DESCRIPTION OF DRAWINGS

FIG. 1 is a diagram of a plasma processing system, describing an example structure.

FIG. 2 is a diagram of a capacitively coupled plasma processing apparatus, describing an example structure.

FIG. 3 is a diagram of an electrostatic chuck (ESC) according to or more embodiments, showing an example structure.

FIG. 4 is a diagram of a ceramic member as viewed from above, showing an example structure.

FIG. 5 is an enlarged view of a peripheral portion of a seal band, showing an example structure.

FIG. 6 is a diagram of a seal band in a comparative example.

FIG. 7 is a diagram of a seal band in a comparative example.

FIG. 8 is a table showing the relationship between a bending degree of a substrate and a distance A.

FIG. 9 is a diagram of a seal band including an inner peripheral portion having a third upper surface and an inclined surface, showing an example structure.

FIG. 10 is a diagram of a seal band including an inner peripheral portion having a third upper surface and an inclined surface, showing an example structure.

FIG. 11 is a diagram of a seal band including an inner peripheral portion having an upper surface being an inclined surface, showing an example structure.

FIG. 12 is a diagram of a seal band including an inner peripheral portion having an inclined surface and a vertical surface, showing an example structure.

FIG. 13 is a diagram of a seal band including an inner peripheral portion having an inclined surface and a vertical surface, showing an example structure.

### DETAILED DESCRIPTION

One or more embodiments of the disclosure will be described below.

An electrostatic chuck according to one or more embodiments is an electrostatic chuck for holding a substrate. The electrostatic chuck includes a dielectric member on which a substrate is placeable, and an electrostatic electrode in the dielectric member. The dielectric member includes a first upper surface having a gas outlet through which a gas flows out, and a seal band being annular. The seal band is outside the first upper surface and at a higher position than the first upper surface. The seal band includes an outer peripheral portion, and an inner peripheral portion having a smaller height than the outer peripheral portion. The electrostatic electrode is at least under the inner peripheral portion of the seal band.

In one or more embodiments, the outer peripheral portion of the seal band has a second upper surface being flat, and the inner peripheral portion of the seal band has a third upper surface being flat.

In one or more embodiments, the inner peripheral portion of the seal band further has an upper surface including an inclined surface.

In one or more embodiments, the third upper surface is at a lower position than the second upper surface and at a higher position than the first upper surface.

In one or more embodiments, the third upper surface is at a lower position than the second upper surface by 0.1 μm or more.

In one or more embodiments, the third upper surface is at a higher position than the first upper surface by 3 μm or more.

In one or more embodiments, the third upper surface is located at a distance of 100 to 750 μm to the electrostatic electrode.

In one or more embodiments, the inner peripheral portion of the seal band has an upper surface being the third upper surface.

In one or more embodiments, the dielectric member further includes a plurality of protrusions on the first upper surface and protruding upward from the first upper surface.

In one or more embodiments, the plurality of protrusions each have a same height as or a smaller height than the outer peripheral portion of the seal band.

In one or more embodiments, the plurality of protrusions each have a height in a range of 5 to 50 μm.

In one or more embodiments, the inner peripheral portion of the seal band has an inner edge between an outer edge of an outermost protrusion of the plurality of protrusions and an inner edge of the outer peripheral portion of the seal band.

In one or more embodiments, the inner peripheral portion of the seal band has an inner edge located inward from a middle point in a radial direction between an outer edge of an outermost protrusion of the plurality of protrusions and an inner edge of the outer peripheral portion of the seal band.

In one or more embodiments, the inner peripheral portion of the seal band has a height being at least a half of a height of each of the plurality of protrusions.

In one or more embodiments, the electrostatic electrode extends from under the first upper surface to under the seal band, and the electrostatic electrode has an outer edge located outward from a middle position of the inner peripheral portion of the seal band in a radial direction.

In one or more embodiments, the outer edge of the electrostatic electrode is under the outer peripheral portion of the seal band.

In one or more embodiments, the outer peripheral portion of the seal band has a width in a radial direction in a range of 0.3 to 4 mm.

In one or more embodiments, the inner peripheral portion of the seal band has a width in a radial direction in a range of 1 to 36 mm.

In one or more embodiments, the inner peripheral portion of the seal band has a larger width than the outer peripheral portion of the seal band in a radial direction.

In one or more embodiments, the inner peripheral portion of the seal band has an upper surface being an inclined surface.

In one or more embodiments, the inner peripheral portion of the seal band has an inclined upper surface and a vertical surface connecting to each other in a radial direction.

In one or more embodiments, the dielectric member has a thickness in a vertical direction in a range of 0.5 to 5 mm.

One or more embodiments of the disclosure will now be described with reference to the drawings. In the drawings, like reference numerals denote like or corresponding components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example Plasma Processing Apparatus

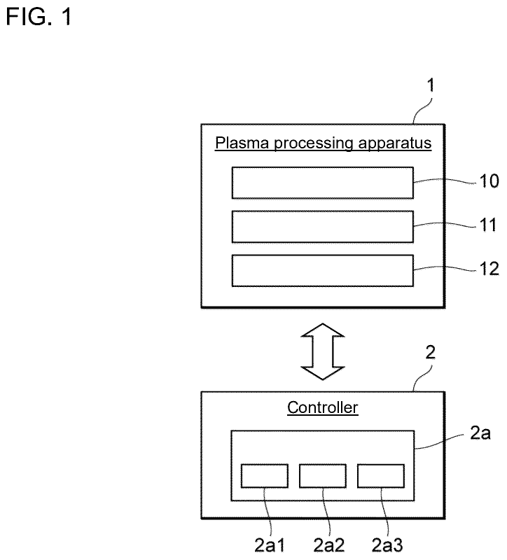

FIG. 1 is a diagram of a plasma processing system, describing an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port for supplying at least one process gas into the plasma processing space and at least one gas exhaust port for discharging the gas from the plasma processing space. The gas supply port is connected to a gas supply 20 (described later). The gas exhaust port is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one embodiment, some or all of the components of the controller 2 may be included in the plasma processing apparatus 1. The controller 2 may include, for example, a computer 2a. The computer 2a may include, for example, a processor (central processing unit or CPU) 2al, a storage 2a2, and a communication interface 2a3. The processor 2al may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2al. The medium may be one of various storage media readable by the computer 2a, or a communication line connected to the communication interface 2a3. The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

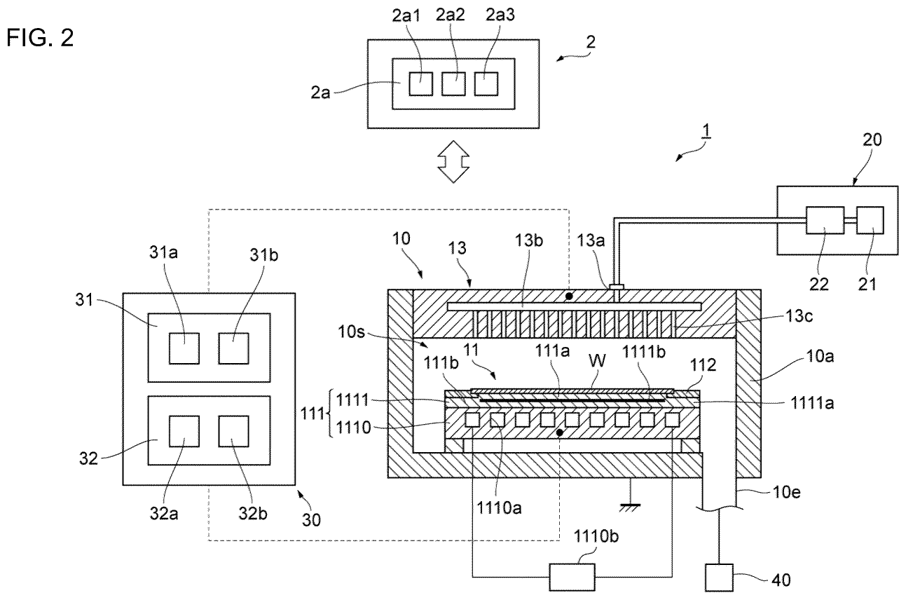

An example structure of a capacitively coupled plasma processing apparatus as an example of the plasma processing apparatus 1 will now be described. FIG. 2 is a diagram of the capacitively coupled plasma processing apparatus, describing an example structure.

A capacitively coupled plasma processing apparatus 1 includes the plasma processing chamber 10, the gas supply 20, a power supply 30, and the exhaust system 40. The plasma processing apparatus 1 also includes the substrate support 11 and a gas inlet unit. The gas inlet unit allows at least one process gas to be introduced into the plasma processing chamber 10. The gas inlet unit includes a shower head 13. The substrate support 11 is located in the plasma processing chamber 10. The shower head 13 is located above the substrate support 11. In one or more embodiments, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a body 111 and a ring assembly 112. The body 111 includes a central portion 111a for supporting a substrate W and an annular portion 1l1b for supporting the ring assembly 112. The substrate W is, for example, a wafer. The annular portion 1l1b of the body 111 surrounds the central portion 111a of the body 111 as viewed in plan. The substrate W is placed on the central portion 111a of the body 111. The ring assembly 112 is placed on the annular portion 1l1b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one or more embodiments, the body 111 includes a base 1110 and an electrostatic chuck (ESC) 1111. The base 1110 includes a conductive member. The conductive member in the base 1110 may serve as a lower electrode. The ESC 1111 is located on the base 1110. The ESC 1111 includes a ceramic member 1111a and an electrostatic electrode 1111b in the ceramic member 1111a. The ceramic member 1111a is an example of a dielectric member. The ceramic member 1111a includes the central portion 1111a. In one or more embodiments, the ceramic member 1111a also includes the annular portion 111b. The annular portion 111b may be included in a separate member surrounding the ESC 1111, such as an annular ESC or an annular insulating member. In this case, the ring assembly 112 may be located on either the annular ESC or the annular insulating member or may be located on both the ESC 1111 and the annular insulating member. An RF electrode or a DC electrode may also be located in the ceramic member 1111a. In this case, the RF electrode or the DC electrode serves as a lower electrode. When a bias RF signal or a DC signal (described later) is provided to the RF electrode or the DC electrode, the RF electrode or the DC electrode is also referred to as a bias electrode. The conductive member in the base 1110 and the RF electrode or the DC electrode may serve as two lower electrodes.

The ring assembly 112 includes one or more annular members. In one or more embodiments, one or more annular members include one or more edge rings and at least one cover ring. The edge ring is formed from a conductive material or an insulating material. The cover ring is formed from an insulating material.

The substrate support 11 may also include a temperature control module that adjusts the temperature of at least one of the ESC 1111, the ring assembly 112, or the substrate to a target temperature. The temperature control module may include a heater, a heat transfer medium, a channel 1110a, or a combination of these. The substrate support 11 may include the channel 1110a in which a heat transfer fluid such as brine or a gas flows. The channel 1110a may be defined in the ESC 1111 or the base 1110. The channel 1110a may connect to a refrigerant supply unit 1110b. A refrigerant adjusted to a predetermined temperature in the refrigerant supply unit 1110b circulates through the channel 1110a to cool the ESC 1111 and the substrate W held by the ESC 1111. In one or more embodiments, the channel 1110a is defined in the base 1110, and one or more heaters are located in the ceramic member 1111a in the ESC 1111. The substrate support 11 may include a heat transfer gas supply to supply a heat transfer gas into a space between the back surface of the substrate W and the central portion 111a.

The shower head 13 introduces at least one process gas from the gas supply 20 into the plasma processing space 10s. The shower head 13 has at least one gas supply port 13a, at least one gas-diffusion compartment 13b, and multiple gas guides 13c. The process gas supplied to the gas supply port 13a passes through the gas-diffusion compartment 13b and is introduced into the plasma processing space 10s through the multiple gas guides 13c. The shower head 13 also includes an upper electrode. In addition to the shower head 13, the gas inlet unit may include one or more side gas injectors (SGIs) installed in one or more openings in the side wall 10a.

The gas supply 20 may include at least one gas source 21 and at least one flow controller 22. In one or more embodiments, the gas supply 20 allows supply of at least one process gas from the corresponding gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes an RF power supply 31 that is coupled to the plasma processing chamber 10 through at least one impedance matching circuit. The RF power supply 31 allows supply of at least one RF signal (RF power), such as a source RF signal or a bias RF signal, to at least one lower electrode, to at least one upper electrode, or to both the electrodes. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the plasma to the substrate W.

In one or more embodiments, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one or more embodiments, the source RF signal has a frequency in a range of 10 to 150 MHz. In one or more embodiments, the first RF generator 31a may generate multiple source RF signals with different frequencies. The generated one or more source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal. In one or more embodiments, the bias RF signal has a lower frequency than the source RF signal. In one or more embodiments, the bias RF signal has a frequency in a range of 100 kHz to 60 MHz. In one or more embodiments, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may include a DC power supply 32 coupled to the plasma processing chamber 10. The DC power supply 32 includes a first DC generator 32a and a second DC generator 32b. In one or more embodiments, the first DC generator 32a is coupled to at least one lower electrode and generates a first DC signal. The generated first DC signal is applied to at least one lower electrode. In one or more embodiments, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses based on DC is applied to at least one lower electrode, to at least one upper electrode, or to both the electrodes. The voltage pulses may have a rectangular, trapezoidal, or triangular pulse waveform, or a combination of these pulse waveforms. In one or more embodiments, a waveform generator for generating a sequence of voltage pulses based on DC signals is coupled between the first DC generator 32a and at least one lower electrode. Thus, the first DC generator 32a and the waveform generator are included in a voltage pulse generator. When the second DC generator 32b and the waveform generator are included in a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31, or the first DC generator 32a may replace the second RF generator 31b.

The exhaust system 40 is connectable to, for example, a gas exhaust port 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

### Example Structure of ESC

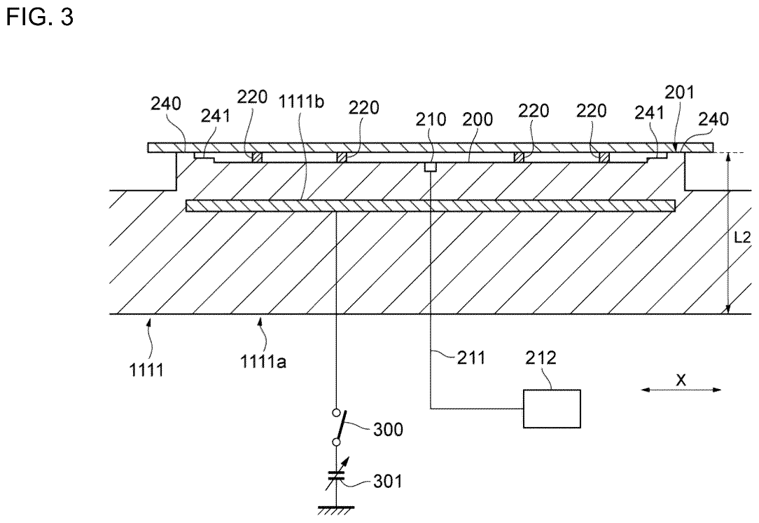

FIG. 3 is a diagram of the ESC 1111 according to an exemplary embodiment, showing an example structure. In one or more embodiments, the ESC 1111 includes the ceramic member 1111a as a dielectric member, and the electrostatic electrode 1111b.

In one or more embodiments, the ceramic member 1111a has a first upper surface 200 and a seal band 201, which is an annular protrusion located outside the first upper surface 200. The seal band 201 is at a higher position than the first upper surface 200. The seal band 201 may be integral with or separate from the first upper surface 200 and other portions of the ceramic member 1111a.

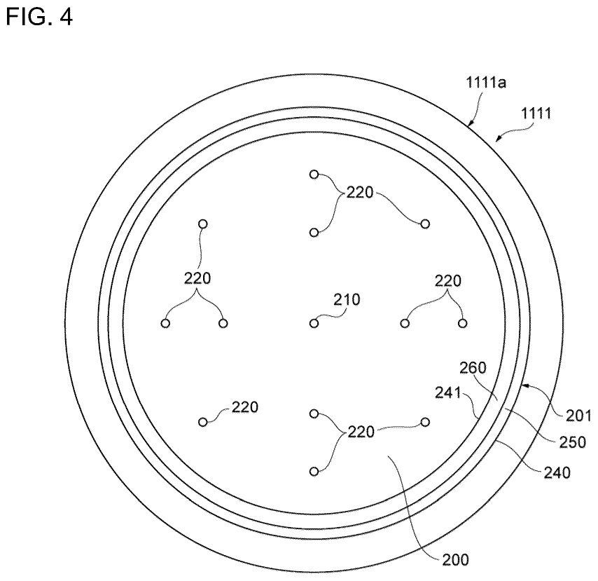

FIG. 4 is a diagram of the ceramic member 1111a as viewed from above, showing an example structure. In one or more embodiments, the first upper surface 200 is circular and has its center at the center of the ceramic member 1111a. The seal band 201 is annular and has its center at the center of the ceramic member 1111a. The annular seal band 201 allows the substrate W electrostatically clamped to come in contact with the upper surface of the seal band 201, preventing the heat transfer gas from leaking into the plasma processing space 10s through a space between the back surface of the substrate W and the ESC 1111.

In one or more embodiments, as shown in FIG. 3, the first upper surface 200 has a gas outlet 210 through which the heat transfer gas flows out. In one or more embodiments, the gas outlet 210 is connected to a heat transfer gas supply 212 through a gas channel 211. The gas channel 211 may extend through the substrate support 11. The heat transfer gas supply 212 may be external to the plasma processing chamber 10. The first upper surface 200 may have one or more gas outlets 210. The heat transfer gas may include a helium gas.

In one or more embodiments, multiple columnar protrusions 220 are on the first upper surface 200. In one or more embodiments, each protrusion 220 protrudes upward from the first upper surface 200. In one or more embodiments, the protrusions 220 are cylindrical. In one or more embodiments, as shown in FIG. 4, the multiple protrusions 220 may be arranged at equal intervals in the circumferential direction about the center of the first upper surface 200. The multiple protrusions 220 may be concentric with or radially arranged from the center of the first upper surface 200.

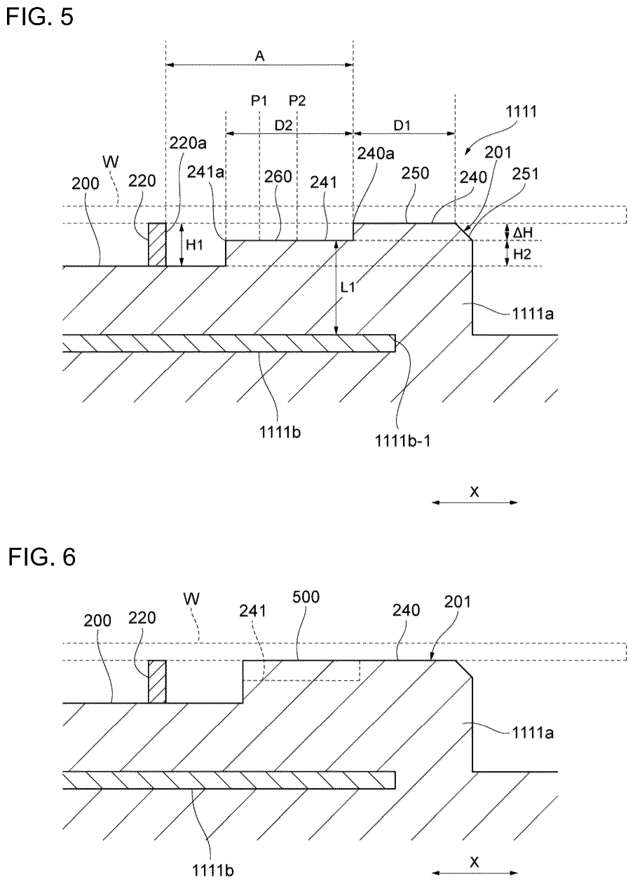

In one or more embodiments, as shown in FIG. 3, the seal band 201 includes an annular outer peripheral portion 240 and an annular inner peripheral portion 241 having a smaller height than the outer peripheral portion 240. The outer peripheral portion 240 is located outside the inner peripheral portion 241 in a radial direction X. FIG. 5 is an enlarged view of a peripheral portion of the seal band 201, showing an example structure.

In one or more embodiments, the outer peripheral portion 240 has a flat second upper surface 250. In one or more embodiments, the outer peripheral portion 240 includes a chamfered portion 251 at the outermost periphery of its upper surface.

In one or more embodiments, the inner peripheral portion 241 has an upper surface being a flat third upper surface 260. In other words, the inner peripheral portion 241 includes no protruding portion or recess on its upper surface. However, as described later, the inner peripheral portion 241 may include a protruding portion on its upper surface.

The third upper surface 260 may be at a lower position than the second upper surface 250 and at a higher position than the first upper surface 200. In other words, the first upper surface 200, the third upper surface 260, and the second upper surface 250 may be stepped outward to be higher in this order in the radial direction X. The second upper surface 250 defines a space for the heat transfer gas to enter between the substrate W and the inner peripheral portion 241. Thus, the substrate W being bent is prevented from coming in contact with the third upper surface 260. The third upper surface 260 may thus be at a lower position than the second upper surface 250 by 0.1 μm or more.

The third upper surface 260 is at a higher position than the first upper surface 200. This structure allows the substrate W to be at a shorter distance from the third upper surface 260, thus increasing the electrostatic attraction to the substrate W in the inner peripheral portion 241. Thus, the seal band 201 can have an electrostatic attraction to the substrate W. The third upper surface 260 may be at a higher position than the first upper surface 200 by 3 μm or more. The third upper surface 260 and the second upper surface 250 (or the upper surface of each protrusion 220) may have a height difference ΔH less than or equal to 7 μm. The third upper surface 260 may have a height H2 that is at least a half of a height H1 of the protrusion 220 from the first upper surface 200. The third upper surface 260 may be located at a distance L1 of 100 to 750 μm to the electrostatic electrode 1111b in the vertical direction.

The third upper surface 260 may include a columnar or annular protruding portion. The protruding portion located nearer the substrate W than the third upper surface 260 allows the inner peripheral portion 241 to have a larger electrostatic attraction to the substrate W. However, the protruding portion located on the third upper surface 260 may have its upper surface in contact with the substrate W, reducing the contact pressure between the substrate W and the outer peripheral portion 240 and possibly causing the heat transfer gas to leak. Thus, the third upper surface 260 may include no protruding portion, or the protruding portion may have an upper surface at a lower position than the second upper surface 250. To increase the electrostatic attraction, the protruding portion may be annular. However, an annular protruding portion may close the space between the protruding portion and the outer peripheral portion 240 when the substrate is being bent, and may prevent the heat transfer gas from entering the space. The protruding portion may thus be columnar.

The inner peripheral portion 241 is between the outermost protrusion 220 and the outer peripheral portion 240. More specifically, the inner peripheral portion 241 has an inner edge 241a between an outer edge 220a of the outermost protrusion 220 and an inner edge 240a of the outer peripheral portion 240. To have a sufficient electrostatic attraction, the inner peripheral portion 241 may have a large area. Thus, the inner peripheral portion 241 may have the inner edge 241a located inward from a middle point P1 in the radial direction X between the outer edge 220a of the outermost protrusion 220 and the inner edge 240a of the outer peripheral portion 240. The inner peripheral portion 241 may extend to the outer edge 220a of the outermost protrusion 220. The inner peripheral portion 241 may have a width D2 larger than a width D1 of the outer peripheral portion 240 in the radial direction X.

However, when the inner peripheral portion 241 is too large, the substrate W may bend and come in contact with the third upper surface 260. FIG. 8 is a table showing the relationship between a distance A (shown in FIG. 5) and the bending degree of the substrate W. The distance A is between the outer edge 220a of the outermost protrusion 220 and the inner edge 240a of the outer peripheral portion 240. Although the inner peripheral portion 241 may extend inward to the position of the outermost protrusion 220, the inner peripheral portion 241 having the width D2 in the radial direction X that is less than or equal to 36 mm allows the bending degree of the substrate W to be less than or equal to about 7 μm. Thus, the width D2 of the inner peripheral portion 241 in the radial direction X may be in a range of 1 to 36 mm.

The protrusion 220 may have the height H1 less than or equal to the height of the outer peripheral portion 240. The protrusion 220 may have the height H1 in a range of 5 to 50 μm.

The outer peripheral portion 240 may have the width D1 in the radial direction X in a range of 0.3 to 4 mm.

As shown in FIG. 3, the electrostatic electrode 1111b may be under the first upper surface 200 and the seal band 201 in the ceramic member 1111a. In one or more embodiments, the electrostatic electrode 1111b is circular. In one or more embodiments, the electrostatic electrode 1111b is coupled to a DC power supply 301 through a switch 300. The DC power supply 301 applies a DC voltage to the electrostatic electrode 1111b, generating an electrostatic attraction (Coulomb force) between the ceramic member 1111a and the substrate W. The substrate W is attracted to the ceramic member 1111a by the electrostatic attraction, and is electrostatically held on the upper surface of the ceramic member 1111a.

In one or more embodiments, as shown in FIG. 5, the electrostatic electrode 1111b extends from under the first upper surface 200 to under the seal band 201. The electrostatic electrode 1111b may be at least under the inner peripheral portion 241. The electrostatic electrode 1111b may have an outer edge 1111b-1 located outward from a middle position P2 of the inner peripheral portion 241 in the radial direction X. The outer edge 1111b-1 may be under the outer peripheral portion 240.

As shown in FIG. 3, the ceramic member 1111a may have a thickness L2 in the vertical direction in a range of 0.5 to 5 mm.

### Example Plasma Processing Method

A plasma processing method includes etching a film on the substrate W with plasma. In one or more embodiments, the plasma processing method is implementable with the controller 2 in the plasma processing apparatus 1.

As shown in FIG. 2, the substrate W is first loaded into the chamber 10 and placed onto the substrate support 11. As shown in FIG. 3, the substrate W is electrostatically held by the ESC 1111. In this state, the substrate W is on the ceramic member 1111a and in contact with the outer peripheral portion 240 of the seal band 201. A DC voltage is applied to the electrostatic electrode 1111b to generate an electrostatic attraction between the seal band 201 and the substrate W, causing the seal band 201 to clamp the substrate W.

In the substrate support 11 shown in FIG. 2, a refrigerant is supplied from the refrigerant supply unit 1110b to the channel 1110a to adjust the temperature of the ESC 1111 and the substrate W held by the ESC 1111 to a predetermined temperature.

A heat transfer gas is supplied from the heat transfer gas supply 212 to the gas outlet 210, and then is supplied through the gas outlet 210 into the space between the substrate W and the first upper surface 200. The heat transfer gas is also supplied into a space between the substrate W and the third upper surface 260. The seal band 201 seals the space between the first upper surface 200 and the substrate W filled with the heat transfer gas to prevent leakage of the heat transfer gas into the plasma processing space 10s. The heat transfer gas adjusts the temperature of the substrate W from the back surface of the substrate W.

Subsequently, a process gas is supplied from the gas supply 20 shown in FIG. 2 to the shower head 13, and then is supplied from the shower head 13 into the plasma processing space 10s. The process gas contains a gas for generating an active species that is to be used for etching the substrate W.

One or more RF signals are provided from the RF power supply 31 to the upper electrode, to the lower electrode, or to both the electrodes. The atmosphere in the plasma processing space 10s may be discharged through the gas exhaust port 10e to decompress the plasma processing space 10s. This generates plasma on the substrate support 11 in the plasma processing space 10s to etch the substrate W. During the plasma processing, the substrate W is cooled by the heat transfer gas supplied through the gas outlet 210 shown in FIG. 3 to the back surface of the substrate W, and by the outer peripheral portion 240 of the seal band 201 adjusted to a predetermined temperature with the refrigerant.

In the exemplary embodiment, the ceramic member 1111a in the ESC 1111 includes the first upper surface 200 and the annular seal band 201. The seal band 201 includes the outer peripheral portion 240 and the inner peripheral portion 241 having a smaller height than the outer peripheral portion 240. The electrostatic electrode 1111b is at least under the inner peripheral portion 241. This creates a space between the inner peripheral portion 241 of the seal band 201 and the substrate W, allowing the heat transfer gas to reach the space above the inner peripheral portion 241. The temperature of the substrate W including the outer peripheral portion of the substrate W is thus adjusted. The inner peripheral portion 241 of the seal band 201 is nearer the substrate W than the first upper surface 200. Thus, the inner peripheral portion 241 of the seal band 201 has a larger electrostatic attraction to the substrate W than the center portion (the portion having the first upper surface 200). Thus, the contact pressure (clamping force per unit area) between the substrate W and the outer peripheral portion 240 increases, causing the substrate W to be strongly clamped on the outer peripheral portion 240. Thus, a small clearance between the substrate W and the outer peripheral portion 240 caused by, for example, surface roughness can be reduced, and the contact area between the substrate W and the outer peripheral portion 240 can be increased, allowing heat to be efficiently transferred between the ESC 1111 and the outer peripheral portion of the substrate W. This allows sufficient cooling of the outer peripheral portion of the substrate W and improves temperature uniformity in the substrate held by the ESC 1111 during plasma processing.

### EXAMPLES

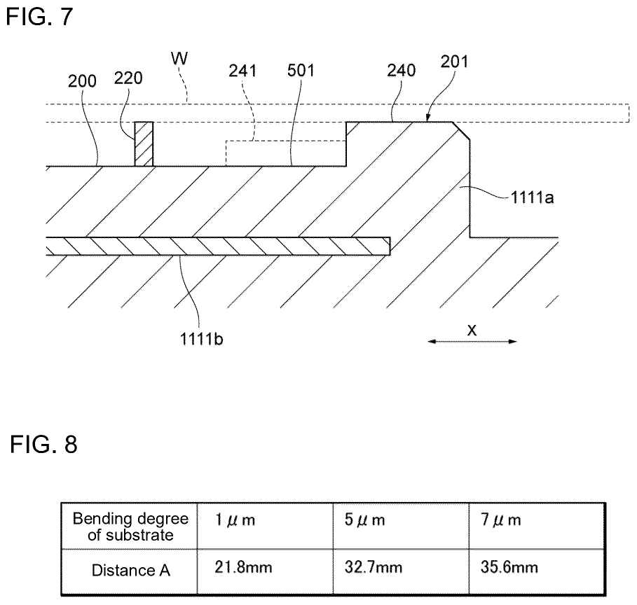

In examples (1) to (3), the contact pressures between the seal band 201 and the substrate are compared. (1) In one example, the seal band 201 includes the inner peripheral portion 241 having a smaller height than the outer peripheral portion 240 as in the exemplary embodiment. (2) In a comparative example, the seal band 201 includes an inner peripheral portion 500 having the same height as the outer peripheral portion 240 as shown in FIG. 6. (3) In another comparative example, the seal band 201 includes an inner peripheral portion 501 at the same height as the first upper surface 200 as shown in FIG. 7. The outer peripheral portion 240 has a width of 1.7 mm in the radial direction X. The inner peripheral portion 241 (500 or 501) has a width of 1.8 mm in the radial direction X. In (1), the third upper surface 260 and the second upper surface 250 have a height difference ΔH of 5 μm. In (2), the outer peripheral portion 240 of the seal band 201 has a substantially larger width in the radial direction than in (1), increasing the contact area between the substrate W and the seal band 201. In (3), the contact area between the substrate W and the seal band 201 is the same as in (1), but the inner peripheral portion 501 is located farther from the substrate W than in (1). When the same voltage is applied to the electrostatic electrode 1111b in each of (1) to (3), the contact pressure is 17.7 kPa in (1), 14.3 kPa in (2), and 16.0 kPa in (3). Thus, heat transfers more in (1) than in (2) or (3) between the substrate W and the seal band 201. When the ESC 1111 holds and cools the substrate W, the measured temperature of the outer peripheral portion of the substrate W in (1) is about 1.5 to 2.2° C. lower than in (2) and (3).

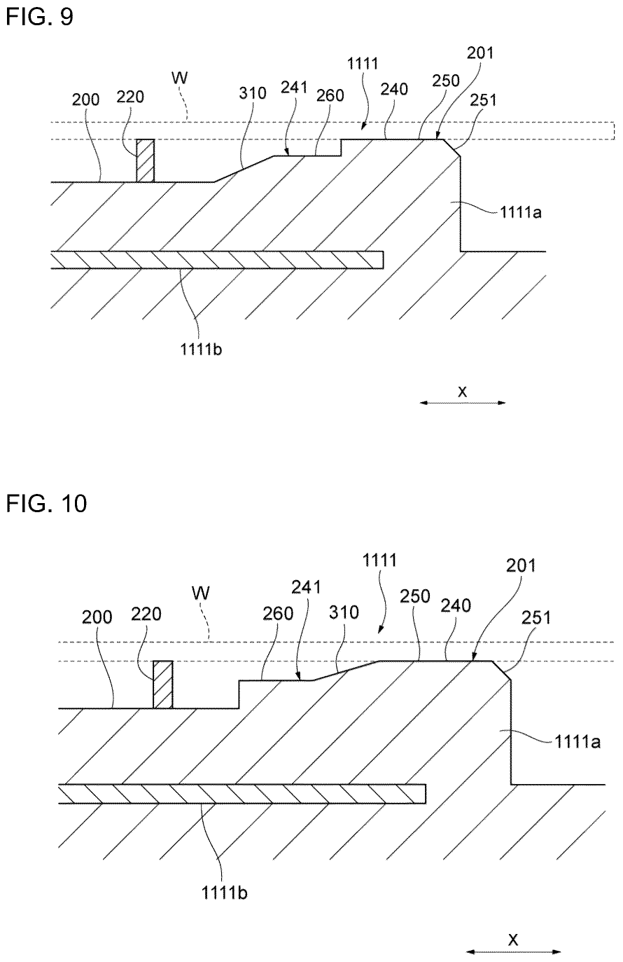

In the above embodiment, the inner peripheral portion 241 of the seal band 201 has the upper surface being the third upper surface 260. However, the inner peripheral portion 241 may further have an inclined surface. In one or more embodiments, as shown in FIG. 9, the inner peripheral portion 241 of the seal band 201 has the third upper surface 260 and an inclined surface 310. The inclined surface 310 and the third upper surface 260 may connect to each other. The inclined surface 310 may have a first edge connecting to the first upper surface 200 and a second edge connecting to the third upper surface 260. In one or more embodiments, as shown in FIG. 10, the inclined surface 310 may have the first edge connecting to the second upper surface 250 and the second edge connecting to the third upper surface 260.

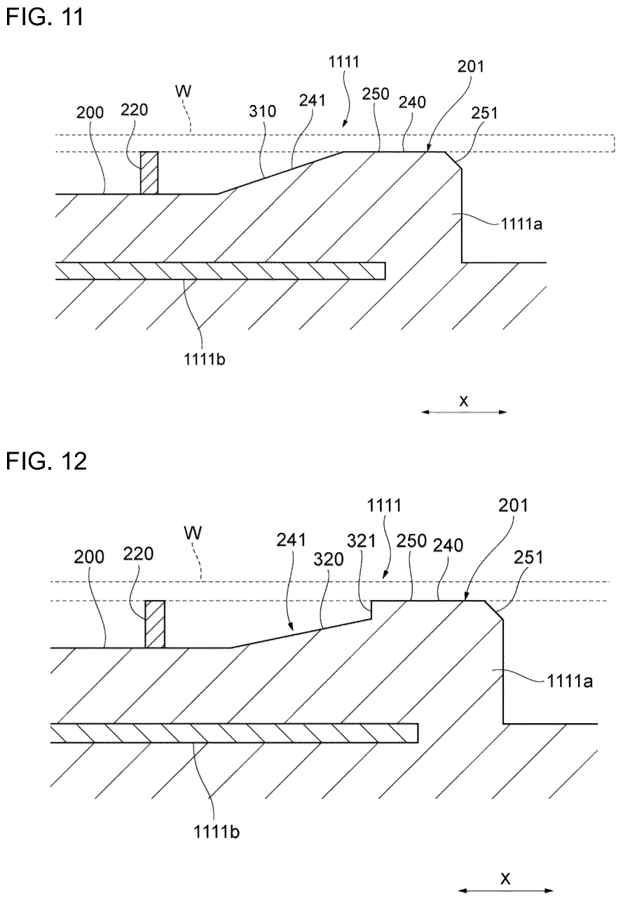

In one or more embodiments, as shown in FIG. 11, the inner peripheral portion 241 of the seal band 201 may have the upper surface being the inclined surface 310.

In one or more embodiments, as shown in FIG. 12, the inner peripheral portion 241 of the seal band 201 may have an inclined upper surface 320 and a vertical surface 321 connecting to each other in the radial direction X. The inclined upper surface 320 may have a first edge connecting to the first upper surface 200 and a second edge connecting to the vertical surface 321. The vertical surface 321 may have a first edge connecting to the inclined upper surface 320 and a second edge connecting to the second upper surface 250.

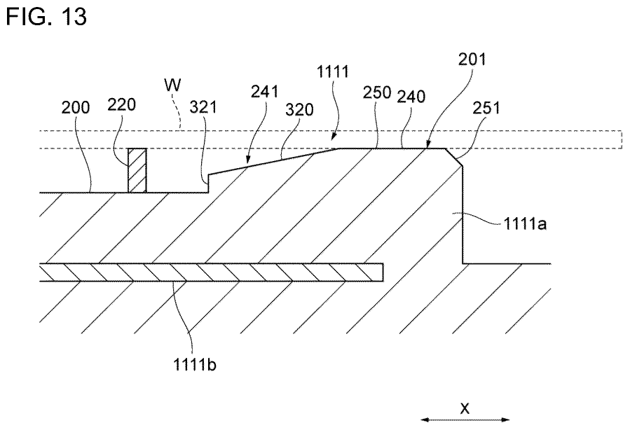

In one or more embodiments, as shown in FIG. 13, the vertical surface 321 may have the first edge connecting to the first upper surface 200 and the second edge connecting to the inclined upper surface 320. The inclined upper surface 320 may have the first edge connecting to the vertical surface 321 and the second edge connecting to the second upper surface 250.

The inclined surface has more electrostatic attraction to the substrate W than the upper surface being the flat third upper surface 260 as shown in FIG. 5, allowing the substrate W to be strongly clamped on the outer peripheral portion 240.

Although the ESC 1111 is used in the capacitively coupled plasma apparatus in the above embodiments, the ESC 1111 may be used in a plasma system of another type. The ESC 1111 may be used in another substrate processing apparatus other than the plasma processing apparatus.

The embodiments of the disclosure further include the aspects described below.

### Appendix 1

An electrostatic chuck for holding a substrate, the electrostatic chuck comprising:
a dielectric member on which a substrate is placeable; and
an electrostatic electrode in the dielectric member,
wherein the dielectric member includes
   a first upper surface having a gas outlet through which a gas flows out, and
   a seal band being annular, the seal band being outside the first upper surface and at a higher position than the first upper surface,
the seal band includes
   an outer peripheral portion, and
   an inner peripheral portion having a smaller height than the outer peripheral portion, and
the electrostatic electrode is at least under the inner peripheral portion of the seal band.

### Appendix 2

The electrostatic chuck according to appendix 1, wherein
the outer peripheral portion of the seal band has a second upper surface being flat, and the inner peripheral portion of the seal band has a third upper surface being flat.

### Appendix 3

The electrostatic chuck according to appendix 2, wherein
the inner peripheral portion of the seal band further has an upper surface including an inclined surface.

### Appendix 4

The electrostatic chuck according to appendix 2 or appendix 3, wherein
the third upper surface is at a lower position than the second upper surface and at a higher position than the first upper surface.

### Appendix 5

The electrostatic chuck according to any one of appendixes 2 to 4, wherein
the third upper surface is at a lower position than the second upper surface by 0.1 μm or more.

### Appendix 6

The electrostatic chuck according to any one of appendixes 2 to 5, wherein
the third upper surface is at a higher position than the first upper surface by 3 μm or more.

### Appendix 7

The electrostatic chuck according to any one of appendixes 2 to 6, wherein
the third upper surface is located at a distance of 100 to 750 μm to the electrostatic electrode.

### Appendix 8

The electrostatic chuck according to any one of appendixes 2 to 7, wherein
the inner peripheral portion of the seal band has an upper surface being the third upper surface.

### Appendix 9

The electrostatic chuck according to any one of appendixes 1 to 8, wherein
the dielectric member further includes a plurality of protrusions on the first upper surface and protruding upward from the first upper surface.

### Appendix 10

The electrostatic chuck according to appendix 9, wherein
the plurality of protrusions each have a same height as or a smaller height than the outer peripheral portion of the seal band.

### Appendix 11

The electrostatic chuck according to appendix 9 or appendix 10, wherein
the plurality of protrusions each have a height in a range of 5 to 50 μm.

### Appendix 12

The electrostatic chuck according to any one of appendixes 9 to 11, wherein
the inner peripheral portion of the seal band has an inner edge between an outer edge of an outermost protrusion of the plurality of protrusions and an inner edge of the outer peripheral portion of the seal band.

### Appendix 13

The electrostatic chuck according to any one of appendixes 9 to 12, wherein
the inner peripheral portion of the seal band has an inner edge located inward from a middle point in a radial direction between an outer edge of an outermost protrusion of the plurality of protrusions and an inner edge of the outer peripheral portion of the seal band.

### Appendix 14

The electrostatic chuck according to any one of appendixes 9 to 13, wherein
the inner peripheral portion of the seal band has a height being at least a half of a height of each of the plurality of protrusions.

### Appendix 15

The electrostatic chuck according to any one of appendixes 1 to 14, wherein
the electrostatic electrode extends from under the first upper surface to under the seal band, and
the electrostatic electrode has an outer edge located outward from a middle position of the inner peripheral portion of the seal band in a radial direction.

### Appendix 16

The electrostatic chuck according to appendix 15, wherein
the outer edge of the electrostatic electrode is under the outer peripheral portion of the seal band.

### Appendix 17

The electrostatic chuck according to any one of appendixes 1 to 16, wherein
the outer peripheral portion of the seal band has a width in a radial direction in a range of 0.3 to 4 mm.

### Appendix 18

The electrostatic chuck according to any one of appendixes 1 to 17, wherein
the inner peripheral portion of the seal band has a width in a radial direction in a range of 1 to 36 mm.

### Appendix 19

The electrostatic chuck according to any one of appendixes 1 to 18, wherein
the inner peripheral portion of the seal band has a larger width than the outer peripheral portion of the seal band in a radial direction.

### Appendix 20

The electrostatic chuck according to any one of appendixes 1 to 19, wherein
the inner peripheral portion of the seal band has an upper surface being an inclined surface.

### Appendix 21

The electrostatic chuck according to any one of appendixes 1 to 20, wherein
the inner peripheral portion of the seal band has an inclined upper surface and a vertical surface connecting to each other in a radial direction.

### Appendix 22

The electrostatic chuck according to any one of appendixes 1 to 21, wherein
the dielectric member has a thickness in a vertical direction in a range of 0.5 to 5 mm.

The above embodiments are mere examples described for illustrative purposes and are not intended to limit the scope of the disclosure. The embodiments may be modified in various ways without departing from the spirit and scope of the disclosure. For example, one or more components in one or more embodiments may be added to the structure according to another embodiment. One or more components in one or more embodiments may be replaced with the corresponding one or more components in another embodiment.

### REFERENCE SIGNS LIST

1 Plasma processing apparatus
10 Chamber
11 Substrate support
112 Ring assembly
1111 Electrostatic chuck
1111a Ceramic member
1111b Electrostatic electrode
200 First upper surface
201 Seal band
240 Outer peripheral portion
241 Inner peripheral portion
250 Second upper surface
260 Third upper surface
W Substrate

1. An electrostatic chuck for holding a substrate, the electrostatic chuck comprising:
a dielectric member on which a substrate is placeable; and
an electrostatic electrode in the dielectric member,
wherein the dielectric member includes:
a first upper surface having a gas outlet through which a gas flows out; and
a seal band being annular, the seal band being outside the first upper surface and at a higher position than the first upper surface,
the seal band includes:
an outer peripheral portion; and
an inner peripheral portion having a smaller height than the outer peripheral portion,
the electrostatic electrode is at least under the inner peripheral portion of the seal band,
the dielectric member further includes a plurality of protrusions on the first upper surface and protruding upward from the first upper surface, and
the inner peripheral portion of the seal band has an inner edge located inward from a middle point in a radial direction between an outer edge of an outermost protrusion of the plurality of protrusions and an inner edge of the outer peripheral portion of the seal band.

2. The electrostatic chuck according to claim 1, wherein
the outer peripheral portion of the seal band has a second upper surface being flat, and
the inner peripheral portion of the seal band has a third upper surface being flat.

3. The electrostatic chuck according to claim 2, wherein
the inner peripheral portion of the seal band further has an upper surface including an inclined surface.

4. The electrostatic chuck according to claim 2, wherein
the third upper surface is at a lower position than the second upper surface and at a higher position than the first upper surface.

5. The electrostatic chuck according to claim 4, wherein
the third upper surface is at a lower position than the second upper surface by 0.1 μm or more.

6. The electrostatic chuck according to claim 5, wherein
the third upper surface is at a higher position than the first upper surface by 3 μm or more.

7. The electrostatic chuck according to claim 2, wherein
the third upper surface is located at a distance of 100 to 750 μm to the electrostatic electrode.

8. The electrostatic chuck according to claim 2, wherein
the upper surface of the inner peripheral portion of the seal band has only the third upper surface.

9. The electrostatic chuck according to claim 1, wherein
the plurality of protrusions each have a same height as or a smaller height than the outer peripheral portion of the seal band.

10. The electrostatic chuck according to claim 1, wherein
the plurality of protrusions each have a height in a range of 5 to 50 μm.

11. The electrostatic chuck according to claim 1, wherein
the inner peripheral portion of the seal band has a height being at least a half of a height of each of the plurality of protrusions.

12. The electrostatic chuck according to claim 1, wherein
the outer peripheral portion of the seal band has a width in the radial direction in a range of 0.3 to 4 mm.

13. The electrostatic chuck according to claim 1, wherein
the inner peripheral portion of the seal band has a width in the radial direction in a range of 1 to 36 mm.

14. The electrostatic chuck according to claim 1, wherein
the inner peripheral portion of the seal band has a larger width than the outer peripheral portion of the seal band in the radial direction.

15. The electrostatic chuck according to claim 1, wherein
an entire upper surface of the inner peripheral portion of the seal band is an inclined surface.

16. The electrostatic chuck according to claim 1, wherein
the inner peripheral portion of the seal band has an inclined upper surface and a vertical surface connecting to each other in the radial direction.

17. The electrostatic chuck according to claim 1, wherein
the dielectric member has a thickness in a vertical direction in a range of 0.5 to 5 mm.

18. The electrostatic chuck according to claim 1, wherein
the electrostatic electrode extends from under the first upper surface to under the seal band, and
the electrostatic electrode has an outer edge located outward from a middle position of the inner peripheral portion of the seal band in the radial direction.

19. The electrostatic chuck according to claim 18, wherein
the outer edge of the electrostatic electrode is under the outer peripheral portion of the seal band.

20. An electrostatic chuck for holding a substrate, the electrostatic chuck comprising:
a dielectric member on which a substrate is placeable; and
an electrostatic electrode in the dielectric member,
wherein the dielectric member includes:
a first upper surface having a gas outlet through which a gas flows out; and
a seal band being annular, the seal band being outside the first upper surface and at a higher position than the first upper surface,
the seal band includes:
an outer peripheral portion; and
an inner peripheral portion having a smaller height than the outer peripheral portion,
the electrostatic electrode is at least under the inner peripheral portion of the seal band, and
the inner peripheral portion of the seal band has a larger width than the outer peripheral portion of the seal band in a radial direction.

21. The electrostatic chuck according to claim 20, wherein
the dielectric member further includes a plurality of protrusions on the first upper surface and protruding upward from the first upper surface, and
the inner peripheral portion of the seal band has a height being at least a half of a height of each of the plurality of protrusions.

22. The electrostatic chuck according to claim 20, wherein
the electrostatic electrode extends from under the first upper surface to under the seal band, and
the electrostatic electrode has an outer edge located outward from a middle position of the inner peripheral portion of the seal band in the radial direction.

23. The electrostatic chuck according to claim 22, wherein
the outer edge of the electrostatic electrode is under the outer peripheral portion of the seal band.

24. The electrostatic chuck according to claim 20, wherein
the outer peripheral portion of the seal band has a width in the radial direction in a range of 0.3 to 4 mm.

25. The electrostatic chuck according to claim 24, wherein
the inner peripheral portion of the seal band has a width in the radial direction in a range of 1 to 36 mm.

26. An electrostatic chuck for holding a substrate, the electrostatic chuck comprising:
a dielectric member on which a substrate is placeable; and
an electrostatic electrode in the dielectric member,
wherein the dielectric member includes:
a first upper surface having a gas outlet through which a gas flows out; and
a seal band being annular, the seal band being outside the first upper surface and at a higher position than the first upper surface,
the seal band includes:
an outer peripheral portion; and
an inner peripheral portion having a smaller height than the outer peripheral portion,
the electrostatic electrode is at least under the inner peripheral portion of the seal band,
the outer peripheral portion of the seal band has a second upper surface being flat, and
the inner peripheral portion of the seal band has a third upper surface being flat and being an inclined surface.

27. An electrostatic chuck for holding a substrate, the electrostatic chuck comprising:
a dielectric member on which a substrate is placeable; and
an electrostatic electrode in the dielectric member,
wherein the dielectric member includes:
a first upper surface having a gas outlet through which a gas flows out; and
a seal band being annular, the seal band being outside the first upper surface and at a higher position than the first upper surface,
the seal band includes:
an outer peripheral portion; and
an inner peripheral portion having a smaller height than the outer peripheral portion,
the electrostatic electrode is at least under the inner peripheral portion of the seal band, and
the inner peripheral portion of the seal band has an inclined upper surface and a vertical surface connecting to each other in a radial direction.
